(19) United States
(12) Patent Application Publication
(10) Pub. No.: US 2015/0085560 A1
(43) Pub. Date: Mar. 26, 2015

(54) RERAM MEMORY CONTROL METHOD AND DEVICE

(71) Applicant: STMicroelectronics SA, Montrouge (FR)

(72) Inventors: Philippe Candelier, Saint Mury Monteymond (FR); Thérèse Andrée Diokh, Grenoble (FR); Joel Damiens, Le Touvet (FR); Elise Le Roux, Grenoble (FR)

(21) Appl. No.: 14/494,383

(22) Filed: Sep. 23, 2014

(30) Foreign Application Priority Data
Sep. 24, 2013 (FR) 1359142

(51) Int. Cl. G11C 13/00

(52) U.S. Cl. CPC G11C 13/0069; G11C 2013/009
USPC 365/148

(57) ABSTRACT

A method of controlling an array of ReRAM cells including programmable-resistance storage elements, including: during a standby period, applying a non-zero standby voltage between electrodes of the storage elements of each cell of the array.

### BACKGROUND

1. Technical Field

The present disclosure generally relates to electronic circuits, and more specifically targets the field of programmable-resistance memories, currently called ReRAMs, for Resistive Random Access Memories.

2. Description of the Related Art

ReRAMs take advantage of the ability of certain materials to change electric resistivity, in reversible and substantially non-volatile fashion, under the effect of a biasing. Conventionally, a ReRAM comprises an array of elementary cells, each comprising a storage element and one or several access transistors. The storage element is essentially formed of two conductive regions or electrodes, separated by a programmable-resistance resistive layer. The application of a properly-selected voltage between the two electrodes modifies the resistance of the resistive layer. Data can thus be recorded in the cells based on resistance values. As an example, a storage element in a lightly-resistive state may correspond to binary value ‘1’, and a storage element in a higher resistive state, such as a highly-resistive state, may correspond to binary value ‘0’.

### BRIEF SUMMARY

In an embodiment, a method of controlling a ReRAM cell having a programmable-resistance storage element, comprises: during a stand-by period, applying a non-zero stand-by voltage between two electrodes of the storage element.

According to an embodiment, the method further comprises: during a period of programming of the storage element to a first resistance value, applying a programming voltage having a first polarity between the two electrodes; and during a period of programming of the storage element to a second resistance value greater than the first value, applying between the two electrodes a programming voltage having a second polarity opposite to the first polarity.

According to an embodiment, the stand-by voltage has the second polarity.

According to an embodiment, the stand-by voltage is from 10 to 200 times lower in absolute value than the programming voltage having the second polarity.

According to an embodiment, the method further comprises, during a period of reading from the storage element, applying between the two electrodes a read voltage lower in absolute value than the programming voltages.

According to an embodiment, the read voltage has the second polarity.

According to an embodiment, the method further comprises, during a period of initialization of the storage element, applying an initialization voltage of the first polarity between the two electrodes.

According to an embodiment, the method further comprises a periodic refreshment of the cell.

According to an embodiment, the storage element comprises a programmable-resistance resistive layer between the two electrodes.

In an embodiment, a device comprises: a plurality of ReRAM cells each comprising a programmable-resistance storage element; and a cell-control circuit capable of implementing the above-mentioned methods.

According to an embodiment, each cell comprises: a first storage element in series with a first transistor between a first node and a second node; a second storage element in series with a second transistor between the first node and a third node; third and fourth transistors respectively between a fourth node and the second node and between a fifth node and the third node; and first and second inverters in antiparallel between the second and third nodes.

According to an embodiment, each cell further comprises a first resistance between the second and fourth nodes, in parallel with the third transistor, and a second resistor between the third and fifth nodes, in parallel with the fourth transistor.

In an embodiment, a method comprises: programming a programmable-resistance storage element of a ReRam cell of an array of ReRam cells during a programming period; and applying a non-zero standby voltage between electrodes of storage elements of each cell of the array of ReRam cells during a stand-by period. In an embodiment, the method comprises: applying a programming voltage having a first polarity between electrodes of the ReRam cell when programming the storage element to a first resistance value; and applying a programming voltage having a second polarity, opposite of the first polarity, between electrodes of the ReRam cell when programming the storage element to a second resistance value greater than the first resistance value. In an embodiment, the standby voltage has the second polarity. In an embodiment, the programming voltage having the second polarity is 10 to 200 times greater in absolute value than the standby voltage. In an embodiment, the method comprises: applying between the electrodes of the ReRam cell a read voltage smaller in absolute value than said programming voltages when reading the storage element. In an embodiment, the read voltage has the second polarity. In an embodiment, the method comprises: applying an initialization voltage having the first polarity between the electrodes of the ReRam cell when initializing the storage element. In an embodiment, the method comprises: periodically refreshing the ReRam cell. In an embodiment, the storage elements comprise a programmable-resistance resistive layer between the electrodes.

In an embodiment, a device comprising: a plurality of ReRAM cells each including a programmable-resistance storage element; and control circuitry coupled to the plurality of ReRAM cells, which, in operation, programs at least one programmable-resistance storage element of a ReRam cell during a programming period; and applies a non-zero standby voltage between electrodes of each programmable-resistance storage element of the plurality of ReRam cells during a stand-by period. In an embodiment, wherein each cell of the plurality of cells comprises: a first storage element in series with a first transistor between a first node and a second node; a second storage element in series with a second transistor between the first node and a third node; third and fourth transistors respectively between a fourth node and the second node and between a fifth node and the third node; and first and second inverters in antiparallel between the second and third nodes. In an embodiment, each cell further comprises a first resistor between the second and fourth nodes, in parallel with the third transistor, and a second resistor between the third and fifth nodes, in parallel with the fourth transistor.

In an embodiment, a device comprises: a plurality of control signal outputs; and control circuitry coupled to the plurality of control signal outputs, which, in operation, generates control signals to, selectively program programmable-resistance storage elements of a plurality of ReRam cells during programming periods; and apply a non-zero standby voltage between electrodes of storage elements of each ReRAM cell of the plurality of ReRam cells during stand-by periods. In an embodiment, the control circuitry, in operation, generates control signals to apply a programming voltage having a first polarity between electrodes of a storage element when programming the storage element to a first resistance value; and generates control signals to apply a programming voltage having a second polarity, opposite of the first polarity, between the electrodes when programming the storage element to a second resistance value greater than the first resistance value. In an embodiment, the standby voltage has the second polarity. In an embodiment, the programming voltage having the second polarity is 10 to 200 times greater in absolute value than the standby voltage. In an embodiment, the control circuitry, in operation, generates control signals to apply between the electrodes a read voltage smaller in absolute value than said programming voltages when reading the storage element. In an embodiment, the read voltage has the second polarity. In an embodiment, the control circuitry, in operation, generates control signals to apply an initialization voltage having the first polarity between the electrodes when initializing the storage element. In an embodiment, the control circuitry, in operation, periodically generates control signals to refresh storage elements. In an embodiment, the device comprises an array of ReRAM cells coupled to the plurality of control signal outputs, each ReRAM cell including at least one storage element having a programmable-resistance resistive layer between two electrodes. In an embodiment, the device comprises an array of ReRAM cells coupled to the plurality of control signal outputs, each ReRAM cell including: a first storage element in series with a first transistor between a first node and a second node; a second storage element in series with a second transistor between the first node and a third node; third and fourth transistors respectively between a fourth node and the second node and between a fifth node and the third node; and first and second inverters in antiparallel between the second and third nodes. In an embodiment, each cell comprises a first resistor between the second and fourth nodes, in parallel with the third transistor, and a second resistor between the third and fifth nodes, in parallel with the fourth transistor.

In an embodiment, a non-transitory computer-readable medium's contents cause control circuitry to control a ReRAM array by generating control signals to, program selected programmable-resistance storage elements of ReRam cells of the array during programming periods; and apply a non-zero standby voltage between electrodes of storage elements of each ReRAM cell of the array during stand-by periods. In an embodiment, the contents cause the control circuitry generate control signals to apply a programming voltage having a first polarity between two electrodes of a storage element when programming the storage element to a first resistance value; and generate control signals to apply a programming voltage having a second polarity, opposite of the first polarity, between the two electrodes when programming the storage element to a second resistance value greater than the first resistance value. In an embodiment, the programming voltage having the second polarity is 10 to 200 times greater in absolute value than the standby voltage.

### BRIEF DESCRIPTION OF THE SEVERAL VIEWS OF THE DRAWINGS

FIG. 1 is an electric diagram illustrating an example of an array of ReRAM cells;

FIG. 2 is a timing diagram illustrating an example of a ReRAM cell control method;

FIG. 3 is a diagram illustrating the current variation in a storage element of a ReRAM cell, according to the voltage applied across this element;

FIG. 4 is a timing diagram illustrating an example of an embodiment of a method for controlling a ReRAM cell;

FIGS. 5, 5A and 5B are electric diagram of embodiments of a ReRAM cell; and

FIG. 6 is a timing diagram illustrating an example of a method for controlling the ReRAM cell of FIG. 5.

### DETAILED DESCRIPTION

For clarity, the same elements have been designated with the same reference numerals in the different drawings, unless the context indicates otherwise.

It should be noted that, in the present application, expressions “highly resistive” and “lightly resistive”, as well as the like expressions (“high resistivity”, “low resistivity”, “high resistivity”, “low resistivity”, etc.) are used relatively to one another, that is, in particular, expression “highly resistive” designates a state of resistivity higher than a resistivity state called “lightly-resistive”.

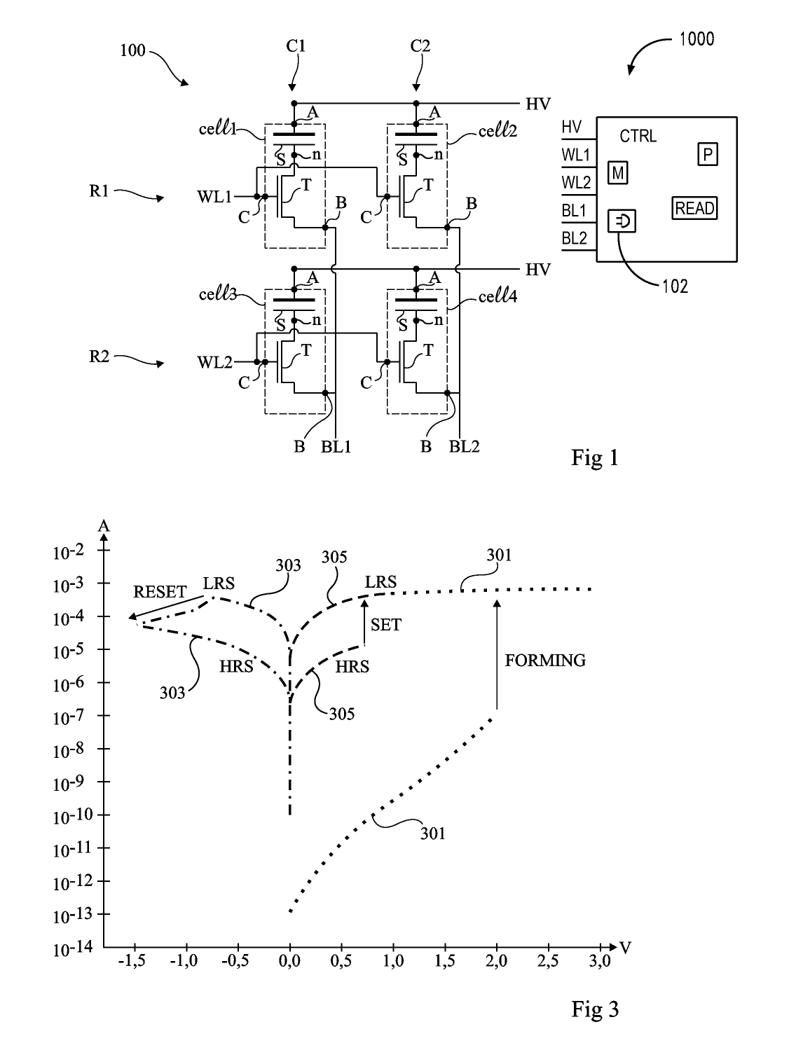

FIG. 1 is an electric diagram of an example of array 100 of ReRAM cells.

In this example, array 100 comprises four identical cells cell1, cell2, cell3, and cell4, arranged along two rows R1 and R2 and two columns C1 and C2. In the shown example, row R1 comprises cells cell and cell2, row R2 comprises cells cell3 and cell4, column C1 comprises cells cell and cell3, and column C2 comprises cells cell2 and cell4. The embodiments and examples which will be described hereafter may of course be adapted to ReRAMs comprising a different number of cells and/or a different cell arrangement.

Each cell of array 100 comprises a storage element S comprising two conductive regions or electrodes, separated by a programmable-resistance layer. As an example, storage element S may be in the form of a stack comprising a first conductive layer forming a first electrode, the resistive layer coating the first conductive layer, and a second conductive layer coating the resistive layer and forming the second electrode. As an example, the first electrode may be made of titanium, the resistive layer may be made of titanium oxide, of tantalum oxide, or of hafnium oxide, and the second electrode may be made of titanium nitride. More generally, the embodiments described hereafter are compatible with all usual materials capable of being used to form a ReRAM storage element.

In this example, each cell of array 100 comprises an access transistor T series-connected with storage element S between nodes A and B of the cell. In this example, the electrodes of storage element S are respectively connected to node A and to an intermediate node n of the cell, and the conduction nodes (source, drain) of transistor T are respectively connected to node n and to node B of the cell. In this example, each cell comprises a node C connected to the gate of transistor T of the cell.

It should be noted that storage element S is an asymmetrical dipole, that is, its behavior depends on the polarity of the voltage applied between its electrodes. Indeed, the programming of element S to a lightly-resistive state is obtained by application of a programming voltage of a given polarity between its electrodes, while the programming of element S to a highly-resistive state is obtained by application of a programming voltage of opposite polarity between its electrodes. It will be considered hereafter that, in each elementary cell of array 100 of FIG. 1, storage element S of the cell is connected so that the programming of element S to a lightly-resistive state is obtained by application of a positive programming voltage between nodes A and n of the cell. However, the examples and embodiments which will be described hereafter may be adapted to the case where storage element S of each cell is connected so that the programming of element S in a lightly-resistive state is obtained by application of a negative programming voltage between nodes A and n of the cell.

In the shown example, nodes A of all the cells in the array are connected to a same node HV, nodes B of all the cells of column C1 are connected to a same node BL1, nodes B of all the cells of column C2 are connected to a same node BL2, nodes C of all the cells of row R1 are connected to a same node WL1, and nodes C of all the cells of row R2 are connected to a same node WL2.

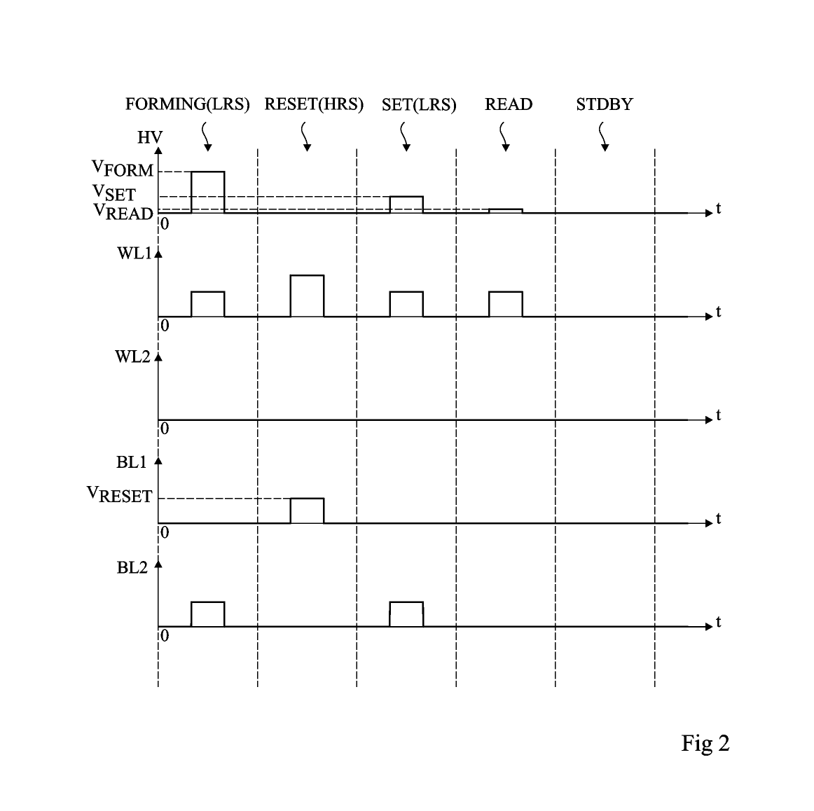

FIG. 2 is a timing diagram illustrating an example of a method for controlling ReRAM cell cell1 of array 100 of FIG. 1. More specifically, FIG. 2 illustrates the time variation of the voltages applied to nodes HV, WL1, WL2, BL1, and BL2 of the array during the different phases of control of cell cell1.

During the first use of cell cell1 after manufacturing, storage element S of the cell is in a highly-resistive state and should be initialized. To achieve this, a relatively high voltage may be applied between nodes A and n of the cell, to create a conductive or lightly resistive path in the resistive layer of storage element S. As will be discussed in further detail hereafter, this path may be then “deleted” and then “recreated” a large number of times by application of respective negative and positive programming voltages, of lower amplitude than the initialization voltage, during cell writing steps.

In this example, in a phase of initialization (FORMING) of cell cell1, node BL1 is set to a reference voltage or ground, for example, in the order of 0 V, node HV is set to a relatively high positive voltage V_{FORM} (with respect to the reference voltage), for example, in the order of 2.5 V, and access transistor T of the cell is turned on by application of a positive voltage, for example, in the order of 1.5 V, on node WL1. It should be noted that the voltages may be selected so that transistor T acts as a current limiter for the cell, to facilitate avoiding deteriorating the cell. In this example, during the phase of initialization (FORMING) of cell cell1, node WL2 is maintained at ground and node BL2 is set to a positive voltage, for example, in the order of 1.5 V, so that the storage elements S of the other cells of array 100 are not submitted to the initialization voltage.

At the end of the initialization phase (FORMING), storage element S of cell cell is in a so-called lightly-resistive state (LRS), for example, corresponding to binary value ‘1’. Element S may then be reprogrammed to a more highly-resistive state (HRS), for example corresponding to binary value ‘0’. To achieve this, a negative programming voltage may be applied between nodes A and n of cell cell1, which suppresses the lightly-resistive path previously formed in the resistive layer of element S.

In this example, in a phase (RESET) of reprogramming cell cell1 to a highly-resistive state (HRS), node HV is grounded, node BL1 is set to a positive voltage V_{RESET} lower than voltage V_{FORM}, for example, in the order of 1.5 V, and access transistor T of the cell is turned on by application of a positive voltage, for example, in the order of 3 V, to node WL1. The voltages are selected so that transistor T conducts a sufficient current to enable the storage element to switch state. During the phase (RESET) of reprogramming cell cell1 to a highly-resistive state (HRS), nodes WL2 and BL2 may be maintained grounded, so that the storage elements S of the other cells of array 100 are not submitted to the reprogramming voltage applied to storage element S of cell cell1.

After a step (RESET) of reprogramming cell cell1 to a highly-resistive state (HRS), storage element S of cell cell1 may again be reprogrammed to a lightly-resistive state (LRS), for example corresponding to binary value ‘1’. To achieve this, a positive reprogramming voltage may be applied between nodes A and n of cell cell1, so that a lightly-resistive path forms again in the resistive layer of element S.

In this example, in a phase (SET) of programming cell cell1 to a lightly-resistive state (LRS), node BL1 is grounded, node HV is set to a positive voltage V_{SET} lower than voltage V_{FORM}, for example, in the order of 1 V, and access transistor T of the cell is turned on by application of a positive voltage, for example, in the order of 1.5 V, to node WL1 (the voltages may be selected to obtain a limitation of the current by transistor T, thus to facilitate avoiding a possible cell deterioration). During the phase (SET) of reprogramming cell cell1 to a lightly-resistive state (LRS), node WL2 is maintained at ground and node BL2 may be set to a positive voltage, for example, in the order of 1.5 V, so that the storage elements S of the other cells of array 100 are not submitted to the reprogramming voltage.

Reading the value stored in cell cell1 amounts to determining whether storage element S of the cell is in a lightly-resistive state (LRS) or in a highly-resistive state (HRS). To achieve this, a relatively low positive voltage, for example, from 10 to 20 times lower than the positive voltage for reprogramming the cell to a resistive state, may be applied between nodes A and n of the cell. The current flowing in storage element S of the cell can then be read and compared with a reference value. A relatively high current corresponds to a low-resistivity state (LRS) of the cell, and a relatively low current corresponds to a high-resistivity state (HRS) of the cell.

In this example, in a phase (READ) of reprogramming cell cell1, node BL1 is grounded, node HV is set to a positive voltage V_{READ} much lower than voltage V_{SET}, for example, in the order of 0.1 V, and access transistor T of the cell is turned on by application of a positive voltage, for example, in the order of 1.5 V, to node WL1. During the reading, the voltages may be selected so that transistor T has a negligible series resistance with respect to that of storage element S, which is desired to be measured. The current flowing in line BL1 of the cell is then read by a read circuit READ to determine the resistivity state of the cell. In this example, during the phase (READ) of reading from cell cell1, node WL2 may be grounded to block access transistors T of cells cell3 and cell4 of row R2, and node BL2 may be grounded, and cell and cell2 of row R1 may be simultaneously read.

In this example, during standby phases (STDBY) of array 100, that is, when the memory is powered but when not initialization, write, or read operation is performed in the array, voltages HV, WL1, WL2, BL1, and BL2 may all be grounded.

A study carried out by the inventors has identified a problem posed by the control method of FIG. 2, which may result in the loss of all or part of the data stored in a ReRAM controlled according to this method. The inventors have observed that the repeated application of a positive read voltage (V_{READ}), even very low, between nodes A and n of a cell programmed in a highly-resistive state (HRS), may result in re-forming a lightly-resistive path in storage element S of this cell. After a number of read operations, storage element S of the cell may switch back to a lightly-resistive state (LRS) under the effect of read voltage V_{READ} alone, thus inducing a data loss.

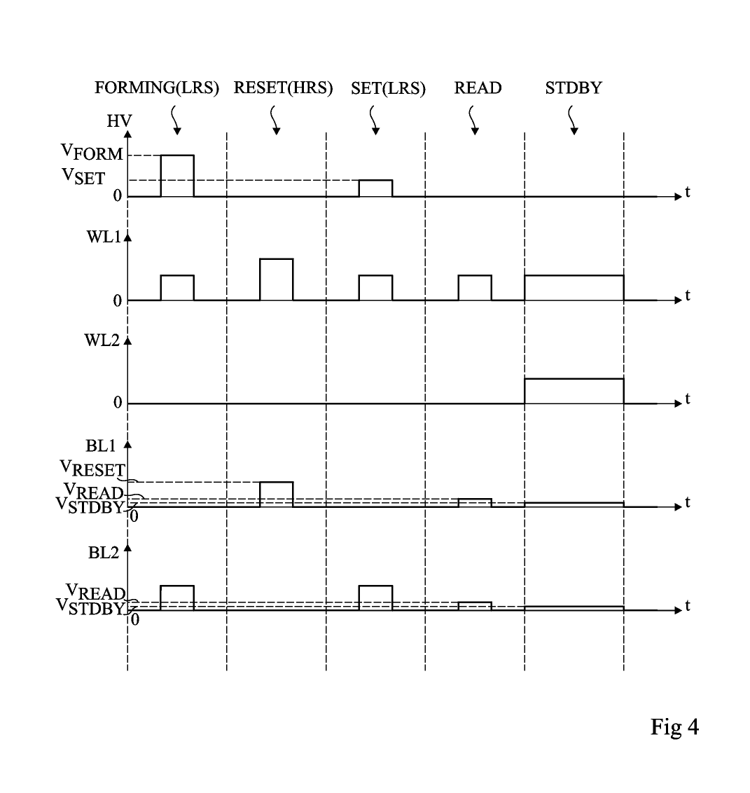

To avoid such a state switching, a periodic refreshment of the cells programmed in a highly-resistive state (HRS), that is, a periodic rewriting of the highly-resistive state (HRS) of these cells by application of a pulse of negative programming voltage V_{RESET} between nodes A and n of these cells, may be provided. However, as illustrated in FIG. 3 which will be described in further detail hereafter, the measurements performed by the inventors show that the transition from the highly-resistive state (HRS) of a cell to its lightly-resistive state (LRS) is an abrupt transition, that is, the resistance of storage element S of the cell abruptly and almost instantaneously jumps from a high value to a low value after a given duration of application of a positive voltage between nodes A and n of the cell, which duration is all the shorter as the applied voltage is high. It is thus difficult, or even impossible to detect in advance, by measurement of the resistance of the cell storage element, that a state switching is about to occur. To ascertain that there will be no data loss, the refreshment should thus be relatively frequent, and should be systematically applied to all the cells programmed in a high resistivity state (HRS). The provision of such a refreshment causes a non-negligible electric power consumption, which may be a problem in certain applications.

FIG. 3 is a diagram illustrating an example of the variation of the resistance of a storage element of a ReRAM cell according to the voltage applied thereacross. More specifically, the diagram of FIG. 3 shows, in abscissas, the voltage, in volts (V), applied between nodes A and n of a cell of array 100 of FIG. 1, and, in ordinates, the current in amperes (A) flowing through storage element S of this cell. The diagram of FIG. 3 corresponds to measurements performed by the inventors on a storage element S comprising a hafnium oxide (HfO₂) layer having an approximate 5-nm thickness between a titanium electrode, on the side of node A of the cell, and a titanium electrode, on the side of node n of the cell. The observed behavior is however representative of the behavior of most known ReRAM storage elements.

Curve 301, in dotted lines in the drawing, shows the variation of the current flowing through the storage element according to the voltage applied between its electrodes during a phase of initialization (FORMING) of the storage element. As appears in curve 301, when a positive voltage is applied between nodes A and n of the cell, the storage element is initially highly resistive, and the current flowing through the storage element is initially very low, in the order of 10⁻⁸ amperes at 1.5 V in this example. When the applied positive voltage reaches a threshold, in the order of 2 V in this example, the resistivity of the storage element abruptly drops, and a much higher current, in the order of some hundred microamperes in this example, starts flowing through the storage element (this current being limited by the current limitation imposed by transistor T). As illustrated in curve 301, the resistivity of the storage element then remains in a low state (LRS), translating as a high current, even when the voltage applied thereacross decreases.

Curve 303, in stripe-dot lines in the drawing, shows the variation of the current flowing in the storage element according to the voltage applied between its electrodes during a phase (RESET) of reprogramming the storage element to a highly-resistive state (HRS). As appears in curve 303, the storage element is initially lightly resistive (LRS) and, when a negative reprogramming voltage is applied between node A and node n of the cell, the current flowing through the storage element is first very high, in the order of some hundred microamperes at −0.5 V in this example. When the applied negative voltage reaches a threshold, in the order of 0.6 V in this example, the resistivity of the storage element starts progressively increasing, to reach the high resistivity programming state (HRS) of the element. As illustrated by curve 303, the resistivity of the storage element then remains in a high state (HRS) even when the amplitude of the applied negative voltage decreases.

Curve 305, a dashed line in the drawing, shows the variation of the current flowing in the storage element according to the voltage applied between its electrodes during a phase (SET) of reprogramming the storage element to a lightly-resistive state (LRS). As appears in curve 305, the storage element is initially highly resistive (HRS) and, when a positive reprogramming voltage is applied between node A and node n of the cell, the current flowing through the storage element is first very low, in the order of 10⁻⁵ amperes at 0.5 V in this example. When the applied positive voltage reaches a threshold, in the order of 0.6 V in this example, the resistivity of the storage element abruptly drops to the low resistivity programming state (LRS) of the element.

Thus, FIG. 3 shows that transitions from the lightly-resistive state (LRS) of storage element S to its highly-resistive state (HRS) are very gradual as compared with transitions from the highly-resistive state (HRS) to the lightly-resistive state (LRS), which are very abrupt. In other words, for a given voltage amplitude applied across element S, the transition from the lightly-resistive state (LRS) to the highly-resistive state (HRS) occurs in a smooth slope, within a relatively long time period, while the transition from the highly-resistive state (HRS) to the lightly-resistive state (LRS) comprises an abrupt resistivity jump within a very short time interval.

According to an embodiment, a method of controlling a ReRAM cell is provided, wherein, during cell stand-by phases, that is, when the cell is powered but no initialization, write, or read operation is performed, a lower bias voltage is applied between the electrodes of the storage element of the cell, which has the same sign but a much lower amplitude, for example, from 10 to 200 lower, than the voltage for programming (RESET) the cell to its highly-resistive state (HRS).

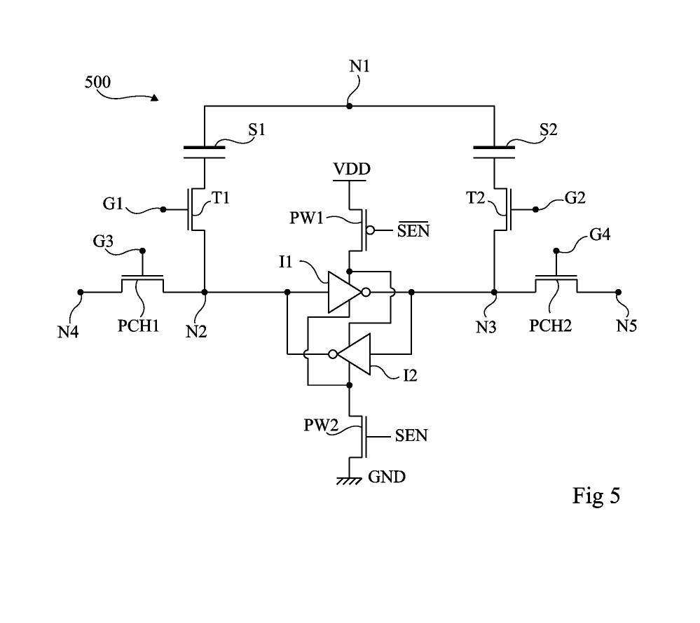

FIG. 4 is a timing diagram illustrating an embodiment of a method of controlling ReRAM cell cell1 of array 100 of FIG. 1. More specifically, FIG. 4 illustrates an example of the time variation of the voltages applied to nodes HV, WL1, WL2, BL1, and BL2 of the array during the different phases of control of cell cell1.

During the phase of initialization (FORMING) of cell cell1, node BL1 is set to a reference voltage or ground, for example, in the order of 0 V, node HV is set to a relatively high positive voltage V_{FORM} (with respect to the reference voltage), for example, in the order of 2.5 V, and access transistor T of the cell is turned on (with, however, a limitation of the current between nodes A and n to facilitate avoiding deteriorating the cell) by application of a positive voltage, for example, in the order of 1.5 V, on node WL1. In this example, during the phase of initialization (FORMING) of cell cell1, node WL2 is maintained at ground and node BL2 is set to a positive voltage, for example, in the order of 1.5 V, so that the storage elements S of the other cells of array 100 are not submitted to the initialization voltage.

During a phase (RESET) of reprogramming cell cell1 to a highly-resistive state (HRS), node HV is grounded, node BL1 is set to a positive voltage V_{RESET} lower than voltage V_{FORM}, for example, in the order of 1.5 V, and access transistor T of the cell is turned on by application of a positive voltage, for example, in the order of 3 V, to node WL1 (during the reprogramming phase, the voltages are selected so that transistor T conducts a sufficient current to enable the storage element to switch state). During the phase (RESET) of reprogramming cell cell1 to a highly-resistive state (HRS), nodes WL2 and BL2 may be maintained at ground, so that the storage elements S of the other cells of array 100 are not submitted to the reprogramming voltage applied to storage element S of cell cell1.

During a phase (SET) of reprogramming cell cell1 to a lightly-resistive state (LRS), node BL1 is grounded, node HV is set to a positive voltage V_{SET} lower than voltage V_{FORM}, for example, in the order of 1 V, and access transistor T of the cell is turned on (with, however, a limitation of the current between nodes A and n to facilitate avoiding deteriorating the cell) by application of a positive voltage, for example, in the order of 1.5 V, to node WL1. During the phase (SET) of reprogramming cell cell1 to a lightly-resistive state (LRS), node WL2 may be maintained at ground and node BL2 may be set to a positive voltage, for example, in the order of 1.5 V, so that the storage elements S of the other cells of array 100 are not submitted to the reprogramming voltage.

In this example, cell cell1 is read by application of a negative voltage (differently from the example of FIG. 2) having a relatively low amplitude, for example, from 5 to 20 times lower than the negative voltage for reprogramming the cell to a highly-resistive state, between nodes A and n of the cell. The current flowing through storage element S of the cell can then be read and compared with a reference value to determine the cell state.

In this example, in a phase (READ) of reprogramming cell cell1, node HV is grounded, node BL1 is set to a positive voltage V_{READ} much lower than voltage V_{RESET}, for example, in the order of 0.1 V, and access transistor T of the cell is turned on by application of a positive voltage, for example, in the order of 1.5 V, to node WL1 (which may be selected to facilitate minimizing the series resistance of transistor T). The current flowing in line BL1 of the cell is then read from by a read circuit READ to determine the resistivity state of the cell. In this example, during the phase (READ) of reading from cell cell1, node WL2 may grounded to block access transistors T of cells cell3 and cell4 of row R2, and node BL2 may be set to voltage V_{READ}, to simultaneously read from cell and cell2 of row R1.

In this example, during standby phases (STDBY) of array 100, that is, when the memory is powered but when initialization, write, or read operation is not performed in the array, voltages HV is grounded, nodes BL1 and BL2 are set to a positive voltage V_{STDBY}, much lower than voltage V_{RESET}, for example, in the order of 0.01 V, and transistors T of the array cells are set to the on state, for example, by application of a positive voltage in the order of 1.5 V to nodes WL1 and WL2.

A control circuit, see control circuit CTRL of FIG. 1, may be provided to apply the above-mentioned control voltages. As illustrated, control circuit CTRL includes a read circuit READ. In some embodiments, the read circuit READ may be separate from the control circuit CTRL. In some embodiments, an integrated circuit 1000 may comprise the array 100, the control circuit CTRL and the read circuit READ. The control circuit CTRL may include one or more processors P, one or more memories M, discrete circuitry 102, and various combinations thereof.

In the embodiment of FIG. 4, during memory stand-by periods (STDBY), the negative biasing of the ReRAM cells sustains the state of the cells programmed with a high resistivity, and facilitates preventing the forming of a new lightly-resistive path in these cells. Thus, an embodiment facilitates decreasing, with respect to the control method of FIG. 2, the probability of unintentional switching of highly-resistive cells to a lightly-resistive state.

In another embodiment, as described in relation with FIG. 4, memory reading operations are carried out under a negative biasing. This further decreases the risk of switching of highly-resistive cells to a low-resistivity state. It should however be noted that the described embodiments are not limited to this specific case. A control method comprising applying a negative biasing to the cells during standby periods and applying a positive biasing during read operations may in particular be envisaged. Some embodiments may perform memory reading operations under positive and/or negative biasing.

In the embodiment of FIG. 4, the main risk of data loss is linked to a possible drift of lightly-resistive cells (LRS) to a highly-resistive state (HRS), especially under the effect of negative standby biasing V_{STDBY} and, possibly, of negative read biasing V_{READ}.

However, unlike the switching from the highly-resistive state (HRS) to the lightly-resistive state (LRS), the drifting from the lightly-resistive state (LRS) to the highly-resistive state (HRS) is a very progressive phenomenon, which is thus easily detectable and controllable. In particular, targeted refreshments of the drifting lightly-resistive cells (LRS) can easily be implemented, with a significant electric power consumption improvement with respect to a systematic refreshment of all the highly-resistive cells (HRS) in the array, of the type described in relation with FIG. 2.

As an example, a refreshment method may periodically comprise, for example, at regular intervals in the order of a few days, reading all memory cells, and reprogramming all the lightly-resistive cells (LRS) having a resistance greater than a threshold (this threshold being lower than the maximum resistance value beyond which a cell is no longer considered as being in the lightly-resistive state, and defining the a maximum tolerated drift). An advantage of an embodiment is that only the cells effectively requiring a refreshment are reprogrammed, which facilitates decreasing the electric power consumption as compared with a systematic refreshment of all the cells of a same resistivity state.

Further, the provided control mode may be particularly advantageous in applications where same data are stored complementarily in distinct ReRAM cell arrays. For each read operation, the two cells of a same pair of complementary cells are read, and the read currents read from the two cells are compared. The sign of the read current difference is used to identify the datum stored in the pair of complementary cells. An advantage of such a read mode, or differential reading, is that it is particularly tolerant to a possible resistance increase of light-resistivity cells (LRS). Indeed, in a pair of complementary cells, as long as the lightly-resistive cell remains less resistive than the highly-resistive cell, the datum can be read by differential reading, and is thus not lost. Refreshments can thus be less frequent than in the case of a simple data storage.

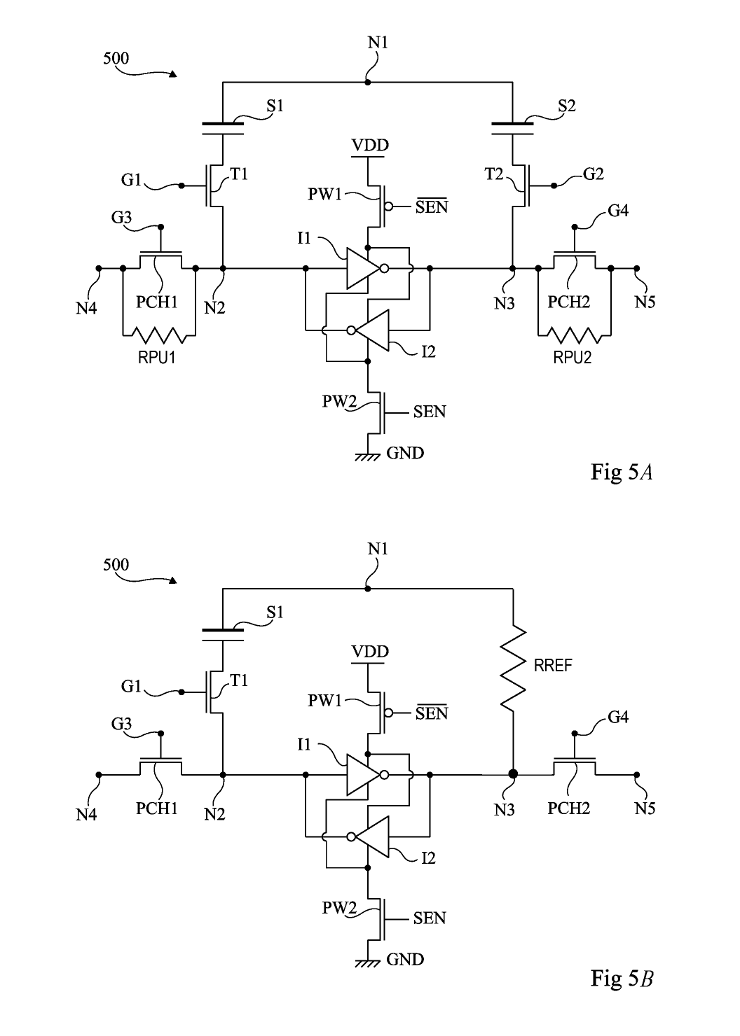

FIG. 5 is an electric diagram of an embodiment of a ReRAM cell 500. In the shown example, the cell is a differential cell, that is, it comprises two ReRAM storage elements S1 and S2 intended to store binary data of opposite values. Storage element S1 is in series with an access transistor T1 between nodes N1 and N2 of the cell, element S1 being on the side of node N1, and storage element S2 is in series with an access transistor T2 between node N1 and a node N3 of the cell, element S2 being on the side of node N1. A transistor PCH1 is connected by its conduction nodes (source, drain) between node N2 and a node N4, and a transistor PCH2 is connected by its conduction nodes (source, drain) between node N3 and a node N5. The gates of transistors T1, T2, PCH1, and PCH2 are respectively connected to nodes G1, G2, G3, and G4 of the cell. Cell 500 further comprises an inverter I1 having an input connected to node N2 and an output connected to node N3, and, in antiparallel, an inverter I2 having an input connected to node N3 and an output connected to node N2. High power supply nodes of inverters I1 and I2 are connected to a high power supply rail VDD via a power supply transistor PW1, and low power supply nodes of inverters I1 and I2 are connected to a low power supply rail GND, for example, the ground, via a power supply transistor PW2. In the shown example, transistors PW1 and PW2 are controlled simultaneously from a same control signal. In this example, transistor PW2 is an N-channel MOS transistor receiving on its gate a control signal SEN, and transistor PW1 is a P-channel MOS transistor receiving on its gate a signal complementary to signal SEN. Thus, when signal SEN is in a high state, transistors PW1 and PW2 are on and inverters I1 and I2 are powered and, when signal SEN is in a low state, transistors PW1 and PW2 are off and inverter I1 and I2 are not powered.

During phases of initialization (FORMING), programming (RESET) of a highly-resistive state (HRS), programming (SET) of a lightly-resistive state (LRS), and standby (STDBY), cell 500 may be controlled according to a control mode similar to what has been described in relation with FIG. 4, provided to replace nodes HV, WL1 and BL1 with nodes N1, G1, and N4, respectively, for the control of element S1, and with nodes N1, G2, and N5, respectively, for the control of element S2. During phases of initialization (FORMING), programming (RESET, SET), and standby (STDBY), transistors PCH1 and PCH2 may be turned on to enable to transfer to nodes N2 and N3 control voltages respectively applied to nodes N4 and N5. Further, during phases of initialization (FORMING), programming (RESET, SET), and standby (STDBY), transistors PW1 and PW2 may be made non-conductive (signal SEN in the low state) to block the supply of inverters I1 and I2.

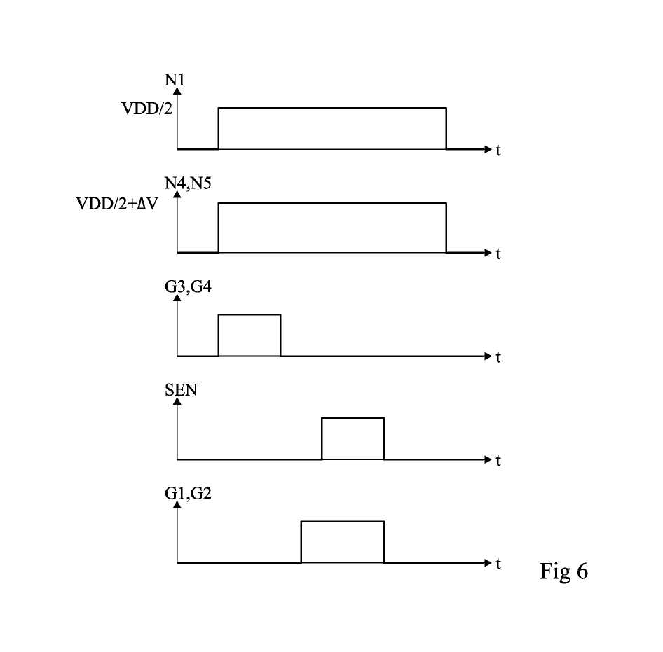

FIG. 6 is a timing diagram illustrating an example of a method for controlling the reading from ReRAM cell 500 of FIG. 5. More specifically, FIG. 6 illustrates the time variation of signal SEN, as well as of the voltages applied to nodes N1, N4, N5, G1, G2, G3, and G4 of cell 500 in a cell read phase (READ).

In a phase of reading (READ) from cell 500, node N1 is set to a voltage ranging between low power supply voltage GND and high power supply voltage VDD of the cell, for example, at voltage VDD/2. Nodes N4 and N5 are set to a same voltage greater by a value ΔV than the voltage of node N1 and lower than high power supply voltage VDD of the cell. Value ΔV corresponds to the negative bias voltage applied to storage elements S1 and S2 of the cell during the reading. As an example, value ΔV may be approximately 100 mV.

The phase of reading (READ) from cell 500 comprises a pre-charge phase during which transistors PCH1 and PCH2 are turned on (signals G3 and G4 in the high state), to charge nodes N2 and N3 to the voltage of nodes N4 and N5, respectively, that is, VDD/2+ΔV in this example. During the pre-charge phase, inverters I1 and I2 are not powered (signal SEN in the low state), and transistors T1 and T2 may be blocked (signals G1 and G2 in the low state). As a variation, transistors T1 and T2 may be conductive (signals G1 and G2 in the high state) during the pre-charge phase.

After the pre-charge phase, transistors PCH1 and PCH2 are blocked (signals G3 and G4 in the low state) and, while the power supply of inverters I1 and I2 is still off (signal SEN in the low state), transistors T1 and T2 are turned on (signals G1 and G2 in the high state). Node N2 then discharges at a speed proportional to the resistance of storage element S1, and node N3 discharges at a speed proportional to the resistance of storage element S2.

After a period of discharge of nodes N2 and N3, transistors PW1 and PW2 are turned on (signal SEN in the high state), to power inverters I1 and I2. When inverters I1 and I2 are powered, they amplify the voltage difference between node N2 and node N3. Thus, if the voltage of node N2 is greater than the voltage of node N3 (element S1 more resistive than element S2), node N2 is taken to high power supply voltage VDD of the inverters and node N3 is taken to low power supply voltage GND of the inverters. If, however, the voltage at node N2 is lower than the voltage at node N3 (element S2 more resistive than element S1), node N2 is taken to voltage GND and node N3 is taken to voltage VDD. To know the value of the datum stored in the cell, the voltage of node N2 and/or of node N3 then just has to be read.

An advantage of the read method described in relation with FIG. 6 is that it enables not only to read the datum stored in cell 500, but also, on each reading, to refresh the stored datum. Indeed, if elements S1 and S2 are respectively in a lightly-resistive state (LRS) and in a highly-resistive state (HRS), during a read step, nodes N2 and N3 are respectively taken to voltages GND and VDD. Node N1 being at an intermediate voltage, that is, VDD/2 in this example, this amounts to applying a relatively high negative bias voltage to element S1, and a relatively high positive bias voltage to element S2, which causes the refreshing of the state of elements S1 and S2. Conversely, if elements S1 and S2 are respectively in a highly-resistive state (HRS) and in a lightly-resistive state (LRS), during a read step, nodes N2 and N3 are respectively taken to voltages VDD and GND. This amounts to applying a negative programming voltage to element S1, and a positive programming voltage to element S2.

As a variation, two resistors RPU1 and RPU2 (see FIG. 5A) may be added to the circuit of FIG. 5, respectively between node N2 and node N4 (in parallel with transistor PCH1) and between node N3 and node N5 (in parallel with transistor PCH2). In this case, storage element S1, transistor T1, and resistor RPU1 form a first dividing bridge, and storage element S2, transistor T2, and resistor RPU2 form a second resistive dividing bridge. During the period of discharge of nodes N2 and N3 (transistors PCH1 and PCH2 off and transistors T1 and T2 on) which follows the cell precharge phase (transistors PCH1 and PGH2 on and transistors T1 and T2 off), the resistances of storage elements S1 and S2 being different, nodes N2 and N3 tend towards different voltages, even when the discharge phase is long, or even tends towards infinity. As a result, the state of the cell can still be read, even if a very long discharge time is provided. This is a difference with respect to the circuit of FIG. 5, where, when the discharge phase is long or tends towards infinity, the voltages of nodes N2 and N3 tend towards a same voltage value, that is, VDD/2, and the states of elements S1 and S2 can no longer be distinguished. Thus, the provision of resistors RPU1 and RPU2 facilitates increasing the time range during which signal SEN can be activated to read the cell state. This enables to increase the flexibility of control and of use of the cell.

As a variation, cell 500 of FIG. 5 may be modified for a simple (non complementary) storage of the data. As shown in FIG. 5B, storage element S2 and transistor T2 may be replaced with a reference resistor RRef, for example, having a value equal to an average or median value between the resistance of a storage element programmed in a highly-resistive state and the resistance of a storage element programmed in a lightly-resistive state.

An example of a control method has been described in relation with FIG. 4 where, during standby periods (STDBY), a negative bias voltage of low amplitude, typically from 10 to 200 times lower than the voltage for programming a high-resistivity state (HRS) is applied to storage elements of ReRAM cells. In the example of FIG. 4, this voltage is applied between nodes A and B of the cell, and access transistor T of the cell is turned on to transfer the voltage between nodes A and n of the cell. As a variation, it may be provided, during standby periods, to maintain access transistor T of the cell off (signal WL1 and WL2 in the low state in this example), and to apply between nodes A and B a relatively high negative bias voltage, typically of the same order of magnitude as the voltage for programming a high-resistivity state (HRS) in the cells. The desired effect of preventing the forming of a lightly-resistive path in highly-resistive cells (HRS) is then obtained via leakage currents flowing through transistor T. Such a control mode is also compatible with cell 500 of FIG. 5.

Further, the described embodiments are not limited to the examples of numerical values mentioned in the present application.

Further, the described embodiments may be adapted to ReRAM cells having other architectures than those described in relation with FIGS. 1 and 5.

the foregoing description is by way of example only and is not intended to be limiting.

Some embodiments may take the form of or include computer program products. For example, according to one embodiment there is provided a computer readable medium including a computer program adapted to perform one or more of the methods or functions described above. The medium may be a physical storage medium such as for example a Read Only Memory (ROM) chip, or a disk such as a Digital Versatile Disk (DVD-ROM), Compact Disk (CD-ROM), a hard disk, a memory, a network, or a portable media article to be read by an appropriate drive or via an appropriate connection, including as encoded in one or more barcodes or other related codes stored on one or more such computer-readable mediums and being readable by an appropriate reader device.

Furthermore, in some embodiments, some of the systems and/or modules and/or circuits and/or blocks may be implemented or provided in other manners, such as at least partially in firmware and/or hardware, including, but not limited to, one or more application-specific integrated circuits (ASICs), digital signal processors, discrete circuitry, logic gates, standard integrated circuits, state machines, look-up tables, controllers (e.g., by executing appropriate instructions, and including microcontrollers and/or embedded controllers), field-programmable gate arrays (FPGAs), complex programmable logic devices (CPLDs), etc., as well as devices that employ RFID technology, and various combinations thereof.

The various embodiments described above can be combined to provide further embodiments. Aspects of the embodiments can be modified, if necessary to employ concepts of the various patents, application and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
programming a programmable-resistance storage element of a ReRam cell of an array of ReRam cells during a programming period; and
applying a non-zero standby voltage between electrodes of storage elements of each cell of the array of ReRam cells during a stand-by period.

2. The method of claim 1, comprising:
applying a programming voltage having a first polarity between electrodes of the ReRam cell when programming the storage element to a first resistance value; and
applying a programming voltage having a second polarity, opposite of the first polarity, between electrodes of the ReRam cell when programming the storage element to a second resistance value greater than the first resistance value.

3. The method of claim 2 wherein the standby voltage has the second polarity.

4. The method of claim 2 wherein the programming voltage having the second polarity is 10 to 200 times greater in absolute value than the standby voltage.

5. The method of claim 2, comprising:
applying between the electrodes of the ReRam cell a read voltage smaller in absolute value than said programming voltages when reading the storage element.

6. The method of claim 5 wherein the read voltage has the second polarity.

7. The method of claim 2, comprising:
applying an initialization voltage having the first polarity between the electrodes of the ReRam cell when initializing the storage element.

8. The method of claim 1, comprising:
periodically refreshing the ReRam cell.

9. The method of claim 1 wherein the storage element comprises a programmable-resistance resistive layer between the electrodes.

10. A device, comprising:
a plurality of ReRAM cells each including a programmable-resistance storage element; and
control circuitry coupled to the plurality of ReRAM cells, which, in operation,
programs a programmable-resistance storage element of at least one ReRam cell during a programming period; and
applies a non-zero standby voltage between electrodes of each programmable-resistance storage element of the plurality of ReRam cells during a stand-by period.

11. The device of claim 10 wherein each cell of the plurality of cells comprises:
a first storage element in series with a first transistor between a first node and a second node;
a second storage element in series with a second transistor between the first node and a third node;
third and fourth transistors respectively between a fourth node and the second node and between a fifth node and the third node; and
first and second inverters in antiparallel between the second and third nodes.

12. The device of claim 11 wherein each cell comprises a first resistor between the second and fourth nodes, in parallel with the third transistor, and a second resistor between the third and fifth nodes, in parallel with the fourth transistor.

13. A device, comprising:
a plurality of control signal outputs; and
control circuitry coupled to the plurality of control signal outputs, which, in operation, generates control signals to,
selectively program programmable-resistance storage elements of a plurality of ReRam cells during programming periods; and
apply a non-zero standby voltage between electrodes of storage elements of each ReRAM cell of the plurality of ReRam cells during stand-by periods.

14. The device of claim 13 wherein the control circuitry, in operation,
generates control signals to apply a programming voltage having a first polarity between electrodes of a storage element when programming the storage element to a first resistance value; and
generates control signals to apply a programming voltage having a second polarity, opposite of the first polarity, between the electrodes when programming the storage element to a second resistance value greater than the first resistance value.

15. The device of claim 14 wherein the standby voltage has the second polarity.

16. The device of claim 14 wherein the programming voltage having the second polarity is 10 to 200 times greater in absolute value than the standby voltage.

17. The device of claim 14 wherein the control circuitry, in operation, generates control signals to apply between the electrodes a read voltage smaller in absolute value than said programming voltages when reading the storage element.

18. The device of claim 17 wherein the read voltage has the second polarity.

19. The device of claim 14 wherein the control circuitry, in operation, generates control signals to apply an initialization voltage having the first polarity between the electrodes when initializing the storage element.

20. The device of claim 13 wherein the control circuitry, in operation, periodically generates control signals to refresh storage elements.

21. The device of claim 13, comprising an array of ReRAM cells coupled to the plurality of control signal outputs, each ReRAM cell including at least one storage element having a programmable-resistance resistive layer between two electrodes.

22. The device of claim 13, comprising an array of ReRAM cells coupled to the plurality of control signal outputs, each ReRAM cell including:
a first storage element in series with a first transistor between a first node and a second node;
a second storage element in series with a second transistor between the first node and a third node;
third and fourth transistors respectively between a fourth node and the second node and between a fifth node and the third node; and
first and second inverters in antiparallel between the second and third nodes.

23. The device of claim 22 wherein each cell further comprises a first resistor between the second and fourth nodes, in parallel with the third transistor, and a second resistor between the third and fifth nodes, in parallel with the fourth transistor.

24. A non-transitory computer-readable medium whose contents cause control circuitry to control a ReRAM array by generating control signals to,
program selected programmable-resistance storage elements of ReRam cells of the array during programming periods; and
apply a non-zero standby voltage between electrodes of storage elements of each ReRAM cell of the array during stand-by periods.

25. The medium of claim 24 wherein the contents cause the control circuitry generate control signals to apply a programming voltage having a first polarity between two electrodes of a storage element when programming the storage element to a first resistance value; and
generate control signals to apply a programming voltage having a second polarity, opposite of the first polarity, between the two electrodes when programming the storage element to a second resistance value greater than the first resistance value.

26. The medium of claim 25 wherein the programming voltage having the second polarity is 10 to 200 times greater in absolute value than the standby voltage.
